(19) United States
(12) Patent Application Publication
(10) Pub. No.: US 2012/0152604 A1
(43) Pub. Date: Jun. 21, 2012

(54) MOUNTING STRUCTURE OF CIRCUIT BOARD HAVING THEREON MULTI-LAYERED CERAMIC CAPACITOR, METHOD THEREOF, LAND PATTERN OF CIRCUIT BOARD FOR THE SAME, PACKING UNIT FOR MULTI-LAYERED CERAMIC CAPACITOR TAPED HORIZONTALLY AND ALIGNING METHOD THEREOF

(75) Inventors: Young Ghyu Ahn, Gyeonggi-do (KR); Byoung Hwa Lee, Gyeonggi-do (KR); Min Cheol Park, Gyeonggi-do (KR); Sang Soo Park, Gyeonggi-do (KR); Dong Seok Park, Seoul (KR)

(73) Assignee: SAMSUNG ELECTRO-MECHANICS CO., LTD., Suwon (KR)

(21) Appl. No.: 13/331,619

(22) Filed: Dec. 20, 2011

(30) Foreign Application Priority Data
Dec. 21, 2010 (KR) 10-2010-0131716

(51) Int. Cl. H05K 1/18; H05K 3/00; H01G 4/30

(52) U.S. Cl. 174/260; 361/301.4; 29/829

(57) ABSTRACT

The present invention provides a method of mounting a circuit board having thereon a multi-layered ceramic capacitor and a land pattern of a circuit board for the same. The method of mounting a circuit board having thereon a multi-layered ceramic capacitor on which a plurality of dielectric sheet having internal electrodes formed thereon are stacked and the external terminal electrodes connected to the internal electrodes in parallel are formed on both ends thereof includes conductively connecting lands of a circuit board to the external terminal electrodes in such a way that internal electrode layers of the multi-layered ceramic capacitor and the circuit board are arranged in a horizontal direction, wherein a height T_{S} of conductive material to conductively connect the external terminal electrodes to the lands is less than ⅓ of a thickness T_{MLCC} of the multi-layered ceramic capacitor.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2010-0131716, entitled filed Dec. 21, 2010, which is hereby incorporated by reference in its entirety into this application.

### BACKGROUND OF THE INVENTION

1. Field of the Invention

The present invention relates to a mounting structure of a circuit board having thereon a multi-layered ceramic capacitor, a method thereof, a land pattern of a circuit board for the same, a packing unit for a multi-layered ceramic capacitor taped horizontally and an aligning method thereof. The present invention enables a vibration noise caused by the multi-layered ceramic capacitor to drastically decrease by forming lands of a circuit board where the multi-layered ceramic capacitor is mounted and conductively connecting the lands to the external terminal electrodes of the multi-layered ceramic capacitor in such a way that internal electrode layers of the multi-layered ceramic capacitor and the circuit board are arranged in a horizontal direction as a method of mounting a circuit board having thereon a multi-layered ceramic capacitor on which a plurality of dielectric sheet having internal electrodes formed thereon are stacked and the external terminal electrodes connected to the internal electrodes in parallel are formed on both ends thereof, wherein a height T_{S} of conductive material to conductively connect the external terminal electrodes to the lands is less than ⅓ of a thickness T_{MLCC} of the multi-layered ceramic capacitor.

2. Description of the Related Art

In general, a multi-layered ceramic capacitor is a SMD (surface mount device) type capacitor and plays an important role of charging or discharging in the circuit of various electronic products such as a mobile phone, a notebook, a computer, a personal digital assistant (PDA).

In general, the multi-layered ceramic capacitor has a structure in which the inner electrodes connected to opposite polarities are alternately stacked with dielectric layers between them.

Such multi-layered ceramic capacitor has been widely used as components of various electronic products due to the advantages of easy mounting, high capacitance and miniaturization.

A ferroelectric material such as barium titanate having a relatively high dielectric constant is usually used as a dielectric material of the multi-layered ceramic capacitor. However, since such ferroelectric material has a piezoelectric property and an electrostrictive property, the mechanical stress and deformation occur when an electric field is applied to such ferroelectric material. In the case that a periodic electric field is applied to the multi-layered ceramic capacitor, the multi-layered ceramic capacitor vibrates by the mechanical deformation due to the piezoelectric property of its ferroelectric material. Such vibrations of the multi-layered ceramic capacitor are transferred to the circuit board having the multi-layered ceramic capacitor thereon.

That is, if an alternative voltage is applied to the multi-layered ceramic capacitor, the stresses Fx, Fy and Fz are generated at a device body of the multi-layered ceramic capacitor according to each direction of X, Y and Z and the vibrations are generated by such stresses. These vibrations are transferred from the multi-layered ceramic capacitor to the circuit board and the vibrations of the circuit board generate acoustic noises.

In the case that the vibration frequency of the circuit board is within audible frequency range (20˜20,000 Hz), such vibration noises give people an unpleasant feeling and therefore it is required to solve these problems.

In recent years, in order to solve such problems, there have been disclosed various technologies such as a technology to prevent the vibration using the elastic deformation of the external terminals of the multi-layered ceramic capacitor, a technology to supplement an additional element to suppress the propagation of vibration generated by the piezoelectric and electrostrictive properties, and a technology to form substrate holes around the multi-layered ceramic capacitor mounted on substrate to suppress the vibration transfer from the multi-layered ceramic capacitor to the substrate. However, they require additional processes and do not give enough effect to prevent vibration noise in comparison with the complexity of processes.

On the other hands, in the multi-layered ceramic capacitors, there is a multi-layered ceramic capacitor having a width equal or similar to a thickness. When the multi-layered ceramic capacitors with the similar width and thickness are mounted on a printed circuit board, are mounted on the printed circuit board irrespective of the directionality of the inner conductors within them. The reason is because the directionality of the inner conductors of the multi-layered ceramic capacitor cannot be recognized from an external appearance of the multi-layered ceramic capacitor with the similar width and thickness.

The difference in electrical and mechanical characteristics of the multi-layered ceramic capacitor can be generated according to the directionality of the inner conductors of the multi-layered ceramic capacitor which is mounted on the printed circuit board; and, particularly, the great difference in the vibration noise can be represented according to its directionality.

Particularly, recent test results show that the correlation between the mounting direction of the multi-layered ceramic capacitor and the amount of conductive material to connect the external electrode terminals of the multi-layered ceramic capacitor to the lands of circuit board influences the vibration noise characteristics greatly.

Particularly, the vibration noise can be drastically reduced in case when the inner electrode surface of the multi-layered ceramic capacitor is mounted horizontally on the surface of the printed circuit board and the height of the conductive material to connect the external electrode terminals of the multi-layered ceramic capacitor to the lands of circuit board is reduced. Therefore, there are needs for a mounting structure, a mounting method, a land pattern of a circuit board, a packing unit for a multi-layered ceramic capacitor taped horizontally and an aligning method thereof to implement these.

### SUMMARY OF THE INVENTION

The present invention has been invented in order to overcome the above-described problems and it is, therefore, an object of the present invention to provide a mounting structure of a circuit board having thereon a multi-layered ceramic capacitor, a method thereof capable of reducing noises generated by vibrations due to a piezoelectric phenomenon, a land pattern of a circuit board for the same, a packing unit for a multi-layered ceramic capacitor taped horizontally and a aligning method thereof.

In accordance with one aspect of the present invention to achieve the object, there is provided a mounting structure of a circuit board having thereon a multi-layered ceramic capacitor on which a plurality of dielectric sheet having internal electrodes formed thereon are stacked and external terminal electrodes connected to the internal electrodes in parallel are formed on both ends thereof, including lands of a circuit board which is conductively connected to the external terminal electrodes in such a way that internal electrode layers of the multi-layered ceramic capacitor and the circuit board are arranged in a horizontal direction, wherein a height _{TS} of conductive material to conductively connect the external terminal electrodes to the lands is less than ⅓ of a thickness T_{MLCC} of the multi-layered ceramic capacitor.

Herein, when the multi-layered ceramic capacitor is packaged with a packing unit such as a reel, a taping is performed to align the multi-layered ceramic capacitors with equal or similar width W_{MLCC} and thickness T_{MLCC} in one direction in such a way that the inner electrodes of the multi-layered ceramic capacitors may be mounted on the circuit board in the horizontal direction. Herein, the equality between the width and the thickness of the multi-layered ceramic capacitor does not means the physical equality but the social standards equality and the similarity between the width and the thickness of the multi-layered ceramic capacitor may be within a range of 0.75≦T_{MLCC}/W_{MLCC}≦1.25.

On the other hands, as the number of dielectric layers within the multi-layered ceramic capacitor is larger or the electric field per thickness of the dielectric layer of the multi-layered ceramic capacitor is higher, the stress and the mechanical deformation due to the piezoelectric phenomenon of the multi-layered ceramic capacitor become large; and, particularly, the vibration noise is significantly generated when the number of dielectric layers is more than 200 layers or when the dielectric layer thickness is less than 3 μm.

Accordingly, the number of dielectric layers of the multi-layered ceramic capacitor may be more than 200 layers and the dielectric thickness of the dielectric layer may be less than 3 μm, wherein the dielectric thickness of the dielectric layer may be less than 3 μm simultaneously while the number of dielectric layers of the multi-layered ceramic capacitor may be more than 200 layers.

In accordance with another aspect of the present invention to achieve the object, there is provided a method of mounting a circuit board having thereon a multi-layered ceramic capacitor on which a plurality of dielectric sheet having internal electrodes formed thereon are stacked and external terminal electrodes connected to the internal electrodes in parallel are formed on both ends thereof, including conductively connecting lands of a circuit board to the external terminal electrodes in such a way that internal electrode layers of the multi-layered ceramic capacitor and the circuit board are arranged in a horizontal direction, wherein a height T_{S} of conductive material to conductively connect the external terminal electrodes to the lands is less than ⅓ of a thickness T_{MLCC} of the multi-layered ceramic capacitor.

Herein, the multi-layered ceramic capacitor with equal or similar width W_{MLCC} and thickness T_{MLCC} is taped to be mounted horizontally on the circuit board.

Also, as described above, the number of dielectric layers of the multi-layered ceramic capacitor may be more than 200 layers and the dielectric thickness of the dielectric layer may be less than 3 μm, wherein the dielectric thickness of the dielectric layer may be less than 3 μm simultaneously while the number of dielectric layers of the multi-layered ceramic capacitor may be more than 200 layers.

Meanwhile, in accordance with still another aspect of the present invention to achieve the object, there is provided a method of mounting a circuit board having thereon a multi-layered ceramic capacitor on which a plurality of dielectric sheet having internal electrodes formed thereon are stacked and external terminal electrodes connected to the internal electrodes in parallel are formed on both ends thereof including: forming lands to mount the multi-layered ceramic capacitor on a surface of the circuit board, wherein the lands of the circuit board are conductively connected to the external terminal electrodes in such a way that internal electrode layers of the multi-layered ceramic capacitor and the circuit board are arranged in a horizontal direction; the lands are formed in a plural number on a surface of the circuit board by being separated so as to correspond to portions on which the external terminal electrodes of the multi-layered ceramic capacitor are formed; and if a width and a length of the multi-layered ceramic capacitor are defined as W_{MLCC} and L_{MLCC} respectively, and a W_{LAND(a)} and a L_{LAND(a)} are defined as a width and a length occupied at the circuit board from an outside edge of any one land among separated lands to an outside edge of another land, it is preferable that a relationship among the W_{MLCC}, the L_{MLCC}, the W_{LAND(a)} and the L_{LAND(a)} is as follows: 0<L_{LAND(a)}/L_{MLCC}, ≦1.2, 0<W_{LAND(a)}/W_{MLCC}≦1.2. Herein, the lands mean the exposed portion without covering with the solder resist.

Meanwhile, in accordance with still another aspect of the present invention to achieve the object, there is provided a mounting structure of a circuit board having thereon a multi-layered ceramic capacitor on which a plurality of dielectric sheet having internal electrodes formed thereon are stacked and external terminal electrodes connected to the internal electrodes in parallel are formed on both ends thereof including: forming lands to mount the multi-layered ceramic capacitor on a surface of the circuit board, wherein the lands of the circuit board are conductively connected to the external terminal electrodes in such a way that internal electrode layers of the multi-layered ceramic capacitor and the circuit board are arranged in a horizontal direction; and the lands are formed in a plural number on a surface of the circuit board by being separated so as to correspond to edge portions of the external terminal electrodes of the multi-layered ceramic capacitor to reduce an amount of soldering.

Herein, if a width and a length of the multi-layered ceramic capacitor are defined as W_{MLCC} and L_{MLCC}, respectively, and a W_{LAND(b)} and a L_{LAND(b)} are defined as a width and a length occupied at the circuit board from an outside edge of any one land among separated lands to an outside edge of another land, a relationship among the W_{MLCC}, the L_{MLCC}, the W_{LAND(b)} and the L_{LAND(b)} is as follows: 0<L_{LAND(b)}/L_{MLCC}, ≦1.2, 0<W_{LAND(b)}/W_{MLCC}≦1.2.

In the method of mounting the circuit board having thereon the multi-layered ceramic capacitor in accordance with the present invention which defines the lands as described above, a height T_{S} of conductive material to conductively connect the external terminal electrodes to the lands is less than ⅓ of a thickness T_{MLCC} of the multi-layered ceramic capacitor.

And also, in the method of mounting the circuit board having thereon the multi-layered ceramic capacitor in accordance with the present invention which defines the lands as described above, when the multi-layered ceramic capacitor is packaged with a packing unit such as a reel, a taping is performed to align the multi-layered ceramic capacitors with equal or similar width W_{MLCC} and thickness T_{MLCC} in one direction in such a way that the inner electrode of the multi-layered ceramic capacitor may be mounted on the circuit board in the horizontal direction. Herein, the equality and the similarity between the width and the thickness of the multi-layered ceramic capacitor may be within a range of 0.75 T_{MLCC}/W_{MLCC}≦1.25.

Meanwhile, in accordance with still another aspect of the present invention to achieve the object, there is provided a land pattern on a circuit board having thereon a multi-layered ceramic capacitor on which a plurality of dielectric sheet having internal electrodes formed thereon are stacked and external terminal electrodes connected to the internal electrodes in parallel are formed on both ends thereof, wherein the land pattern is formed in a plural number on a surface of the circuit board by being separated so as to correspond to portions of the external terminal electrodes of the multi-layered ceramic capacitor, wherein if a width and a length of the multi-layered ceramic capacitor are defined as W_{MLCC} and L_{MLCC}, respectively, and a W_{LAND(a)} and a L_{LAND(a)} are defined as a width and a length occupied at the circuit board from an outside edge of any one land among separated lands to an outside edge of another land, a relationship among the W_{MLCC}, the L_{MLCC}, the W_{LAND(a)} and the L_{LAND(a)} is as follows: 0<L_{LAND(a)}/L_{MLCC}, ≦1.2, 0<W_{LAND(a)}/W_{MLCC}≦1.2.

And also, in accordance with still another aspect of the present invention to achieve the object, there is provided a land pattern on a circuit board having thereon a multi-layered ceramic capacitor on which a plurality of dielectric sheet having internal electrodes formed thereon are stacked and external terminal electrodes connected to the internal electrodes in parallel are formed on both ends thereof, wherein the land pattern is formed in a plural number on a surface of the circuit board by being separated so as to correspond to edge portions of the external terminal electrodes of the multi-layered ceramic capacitor to reduce an amount of soldering, wherein if a width and a length of the multi-layered ceramic capacitor are defined as W_{MLCC} and L_{MLCC}, respectively, and a W_{LAND(b)} and a L_{LAND(b)} are defined as a width and a length occupied at the circuit board from an outside edge of any one land among separated lands to an outside edge of another land, it is preferable that a relationship among the W_{MLCC}, the L_{MLCC}, the W_{LAND(b)} and the L_{LAND(b)} is as follows: 0<L_{LAND(b)}/L_{MLCC}, ≦1.2, 0<W_{LAND(b)}/W_{MLCC}≦1.2.

Meanwhile, in accordance with still another aspect of the present invention to achieve the object, there is provided a packing unit for a multi-layered ceramic capacitor including: the multi-layered ceramic capacitor on which a plurality of dielectric sheet having internal electrodes formed thereon are stacked and external terminal electrodes connected to the internal electrodes in parallel are formed on both ends thereof; and a packing sheet including a storing space to contain the multi-layered ceramic capacitor, wherein internal electrodes of the multi-layered ceramic capacitors are aligned to be horizontally arranged with reference to a bottom surface of the storing space.

Herein, the packing unit for the multi-layered ceramic capacitor further includes a packing layer which is coupled to the packing sheet and covers the multi-layered ceramic capacitor.

Herein, the packing unit for the multi-layered ceramic capacitor is wound in a shape of reel.

On the other hands, in accordance with still another aspect of the present invention to achieve the object, there is provided a method of aligning a multi-layered ceramic capacitor having a thickness T_{MLCC} equal or similar to a width W_{MLCC} in a horizontal direction including: mounting the multi-layered ceramic capacitor on a transferring unit to transfer continuously; and supplying magnetic field to align the multi-layered ceramic capacitor transferred in the transferring unit.

Herein, the inner electrode layer of the multi-layered ceramic capacitor passed through supplying magnetic field is arranged horizontally with reference to a bottom plane of the transferring unit.

Herein, the transferring unit further includes a pair of guide units to align the multi-layered ceramic capacitor.

Herein, if a gap between the pair of guide units and a width, a thickness and a length of the multi-layered ceramic capacitor are defined as g, W_{MLCC}, T_{MLCC} and L_{MLCC}, respectively, the following relationship is satisfied:

\sqrt{(W²_{MLCC}+T²_{MLCC})}<g<min[\sqrt{(L²_{MLCC}+T²_{MLCC})},

\sqrt{(L²_{MLCC}+W²_{MLCC})}]

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a structure to mount a multi-layered ceramic capacitor horizontally on a circuit board in accordance with an embodiment of the present invention;

FIG. 2 is a diagram showing a multi-layered ceramic capacitor a having a thickness equal or similar to a width thereof and a multi-layered ceramic capacitor b having a width greater than a thickness thereof;

FIG. 3 is a plan view showing a circuit board having a land pattern in accordance with another embodiment of the present invention;

FIG. 4 is a simulation diagram for showing a relationship between a land and a width and a length of the multi-layered ceramic capacitor in accordance with still another embodiment of the present invention;

FIG. 5 is a plan view showing a circuit board in accordance with still another embodiment of the present invention;

FIG. 6 is a simulation diagram for showing a relationship between a land and a width and a length of the multi-layered ceramic capacitor in accordance with still another embodiment of the present invention;

FIG. 7 is a diagram showing a packing unit for a multi-layered ceramic capacitor arranged in parallel in accordance with still another embodiment of the present invention;

FIG. 8 is a diagram showing a packing unit for a multi-layered ceramic capacitor wound in a shape of reel in accordance with still another embodiment of the present invention;

FIG. 9 is a simulation diagram showing a status that a multi-layered ceramic capacitor is aligned by a magnetic field;

FIG. 10 and FIG. 11 are simulation diagrams showing views aligned by a magnetic field while a multi-layered ceramic capacitor is transferred by a transferring unit;

FIG. 12 is a simulation diagram showing a horizontal direction alignment method of a multi-layered ceramic capacitor in accordance with still another embodiment of the present invention;

FIG. 13 is a simulation diagram showing a case (a) when a multi-layered ceramic capacitor is horizontally mounted on a circuit board and a case (b) when a multi-layered ceramic capacitor is vertically mounted on a circuit board as test examples of the present invention;

FIG. 14 is a graph showing an effect that a height of a conductive material (solder) has on a vibration noise when a multi-layered ceramic capacitor is horizontally or vertically mounted on a circuit board as test examples of the present invention; and

FIG. 15 is a graph showing an effect that a size of a land has on a vibration noise when a multi-layered ceramic capacitor is horizontally or vertically mounted on a circuit board as test examples of the present invention.

### DETAILED DESCRIPTION OF THE PREFERABLE EMBODIMENTS

Hereinafter, specific embodiments of the present invention will be described with reference to the accompanying drawings. However, the following embodiments are provided as examples but are not intended to limit the present invention thereto.

Descriptions of well-known components and processing techniques are omitted so as not to unnecessarily obscure the embodiments of the present invention. The following terms are defined in consideration of functions of the present invention and may be changed according to users or operator's intentions or customs. Thus, the terms shall be defined based on the contents described throughout the specification.

The technical spirit of the present invention should be defined by the appended claims, and the following embodiments are merely examples for efficiently describing the technical spirit of the present invention to those skilled in the art.

At first, the present invention will be explained in detail with reference to the accompanying drawings as follows.

### A Mounting Structure of a Circuit Board Having Thereon a Multi-Layered Ceramic Capacitor and a Mounting Method Thereof

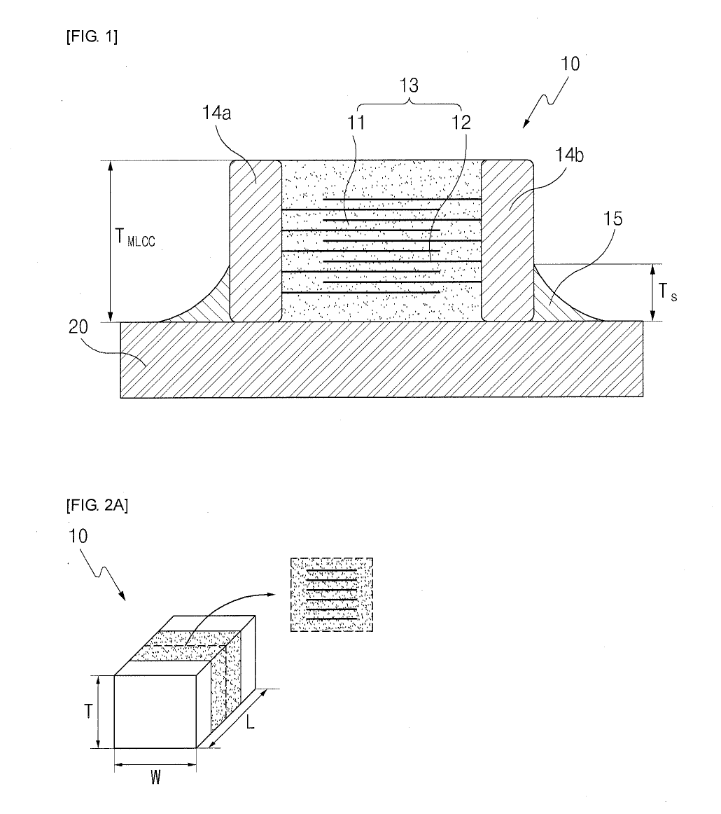

FIG. 1 is a cross-sectional view showing a structure to mount a multi-layered ceramic capacitor 10 horizontally on a circuit board in accordance with an embodiment of the present invention.

A structure and a method of mounting a circuit board 20 having thereon a multi-layered ceramic capacitor 10 includes stacking a dielectric sheet 11 having internal electrodes 12 formed thereon, forming external terminal electrodes 14a and 14b to connect the internal electrode 12 in parallel on both ends of the multi-layered ceramic capacitor 10, forming lands (not shown in FIG. 1) on a surface of the circuit board 20 to mount the multi-layered ceramic capacitor 10, and conductively connecting the lands to the external terminal electrodes 14a and 14b by arranging the inner electrode layer 12 of the multi-layered ceramic capacitor 10 in a horizontal direction with reference to the surface of the circuit board 20, wherein a height T_{S} of a conductive material 15 to conductively connect the external terminal electrodes 14a and 14b to the lands is less than ⅓ of a thickness T_{MLCC} of the multi-layered ceramic capacitor.

As shown in FIG. 1, the multi-layered ceramic capacitor 10 includes a body 13 formed by alternately stacking the dielectric layer 11 and the internal electrode 12, and the pair of external electrodes 14a and 14b to alternately connect the internal electrode 12 in parallel at both ends of the body 13.

The dielectric layer 11 is made of a ferroelectric material mainly composed of barium titanate or the like and can be made of the other ferroelectric materials.

The internal electrode 12 is made of a thin metal formed by sintering a metal paste and the metal paste can be composed of metal materials such as Ni, Pd, Ag—Pd, Cu or the like as main components.

The pair of external electrodes 14a and 14b are made of a metal material such as Cu and Ni or the like and a plating is performed on the surfaces of the external electrodes 14a and 14b in order to improve the wetting property of solder.

Lands are formed on a surface of circuit board 20 to mount the multi-layered ceramic capacitor 10, wherein the lands mean the exposed portions of metal pad without being covered with the solder resist. Herein, the circuit board 20 can be a multi-layered circuit board and the like and there is no limitation in a type thereof.

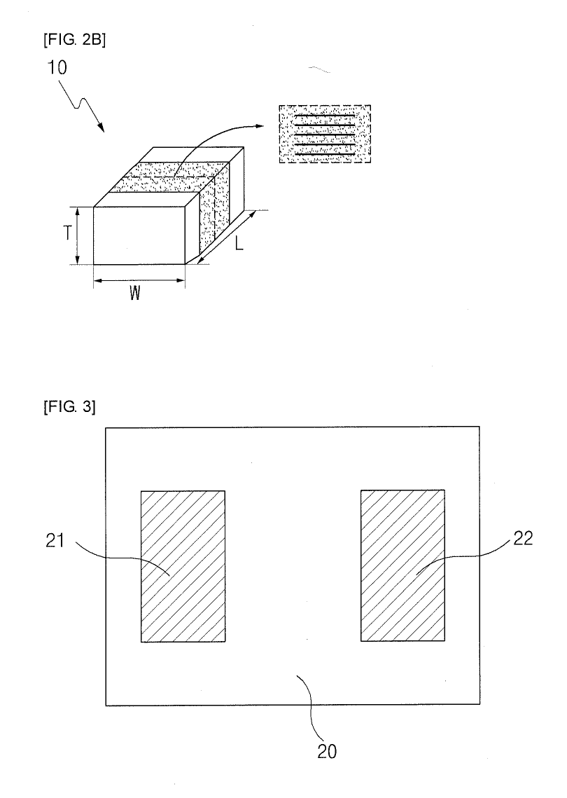

As shown in FIG. 2, a width W of the multi-layered ceramic capacitor 10 may be equal or similar to a thickness T thereof (see FIG. 2a) and a width of the multi-layered ceramic capacitor 10 is greater than a thickness thereof (see FIG. 2b). For the latter case, it always becomes the horizontal mounting due to its slim thickness, but, for the former case, the horizontal mounting and the vertical mounting are randomly performed. Herein, the equality and the similarity between the width W_{MLCC} and the thickness T_{MLCC} of the multi-layered ceramic capacitor 10 may be within a range of 0.75≦T_{MLCC}/W_{MLCC}≦1.25.

As the conductive material 15 such as solder plays a role of a vibration medium between the multi-layered ceramic capacitor 10 and the circuit board 20, the vibration transfer from the multi-layered ceramic capacitor to the circuit board deteriorates as lowering the height of the conductive material 15. In the case of the horizontal mounting of the multi-layered ceramic capacitor on the circuit board, the main vibration surface of the multi-layered ceramic capacitor is estimated to be parallel to the surface of the circuit board. The vibration of the top surface of the multi-layered ceramic capacitor in the horizontal mounting is difficult to transfer to the circuit board in the case of low height of conductive material because there is no vibration medium around its top surface due to low height of conductive material. Therefore, as the height of conductive material becomes low, the vibration noise greatly decreases in the case of the horizontal mounting of the multi-layered ceramic capacitor on the circuit board.

On the other hands, in the case of the vertical mounting of the multi-layered ceramic capacitor on the circuit board, the main vibration surface of the multi-layered ceramic capacitor is estimated to be perpendicular to the surface of the circuit board. The vibration of the side surface of the multi-layered ceramic capacitor in the vertical mounting can be transferred to the circuit board even in the case of low height of conductive material because there is a vibration medium around the bottom portion of its side surface in spite of low height of conductive material. Therefore, as the height of conductive material becomes low, the vibration noise decreases slowly in the case of the vertical mounting of the multi-layered ceramic capacitor on the circuit board but the decrease of vibration noise in the vertical mounting is much less than that in the horizontal mounting.

Accordingly, in order to reduce the vibration noise due to the multi-layered ceramic capacitor 10, it is preferable that the multi-layered ceramic capacitor 10 is mounted in the horizontal direction that means the internal electrode 12 thereof is parallel with the surface of the circuit board 20 and the height of the conductive material 15 is reduced.

The sizes of the multi-layered ceramic capacitor 10 may be 0603(L×W=0.6 mm×0.3 mm), 1005, 1608, 2012, 3216 and 3225 or the like according to the width W and the length L of the multi-layered ceramic capacitor 10 of FIG. 2. In case when the size of the multi-layered ceramic capacitor 10 is equal to or larger than 3216, since the absolute amount of the conductive material 15 is much even though a relative height of the conductive material in comparison with the thickness of the multi-layered ceramic capacitor 10 is low, it is preferable that a relative height of the conductive material 15 is below ¼ in order to increase the reduction effect of the vibration noise.

Although the conductive material 15 has not a specific limitation as a material to conduct electricity for the electric connection between the circuit board 20 and the multi-layered ceramic capacitor 10, but it is common that the solder is used.

Land Pattern

FIG. 3 is a plan view showing a circuit board having a land pattern in accordance with another embodiment of the present invention.

Herein, the multi-layered ceramic capacitor 10 is mounted on the lands 21 and 22 of the circuit board 20 and the lands 21 and 22 can be formed in plural number by being separated to correspond to portions where the external terminal electrodes 14a and 14b of the multi-layered ceramic capacitor 10 of FIG. 1 are formed. Herein, the lands 21 and 22 mean the exposed portions without being covered with the solder resist.

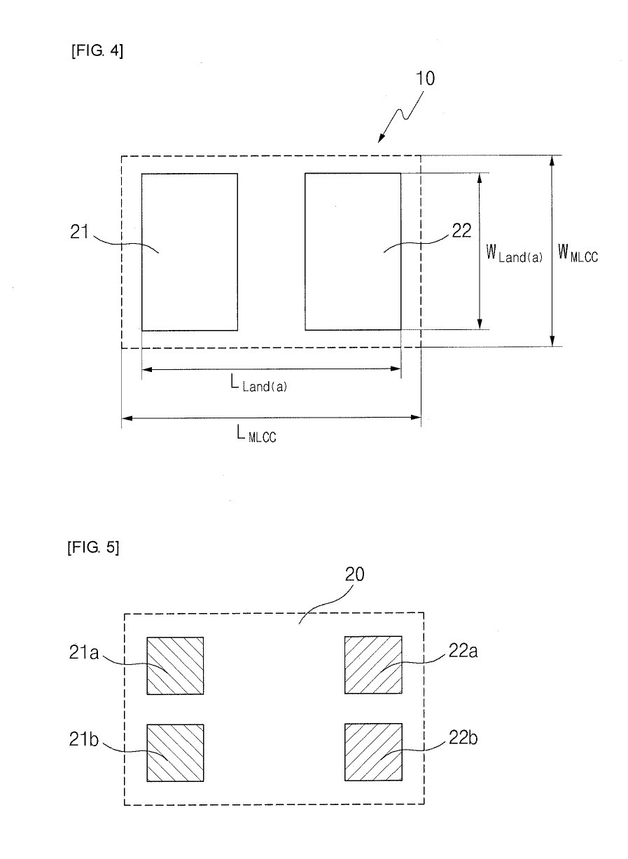

Although, in FIG. 3, it is shown that the figure to form two lands in a shape of rectangle is represented as one embodiment, but there is no limitations for the shape thereof. However, since the height of conductive material 15 on the surfaces of the lands 21 and 22 affects the vibration noise as described the above, the height of the conductive material 15 can be reduced by putting a certain limitation in the areas occupied by the lands 21 and 22 as shown in the following FIG. 4.

FIG. 4 is a simulation diagram for showing a relationship between the lands 21 and 22 and a width and a length of the multi-layered ceramic capacitor 10 in accordance with still another embodiment of the present invention. The width and the length of the multi-layered ceramic capacitor 10 are defied as W_{MLCC} and L_{MLCC}, respectively, as shown in FIG. 4. In case when the width and the length occupied in the substrate with reference to the outer edges of one land 21 and the other land 22 are defined as W_{LAND(a)} and L_{LAND(a)}, respectively, as shown in FIG. 4, it is preferable that a relationship among the W_{MLCC}, the L_{MLCC}, the W_{LAND(a)} and the L_{LAND(a)} is as follows 0<L_{LAND(a)}/L_{MLCC}≦1.2, 0<W_{LAND(a)}/W_{MLCC}≦1.2. In the case of deviating from the range above, the large amount of the conductive material 15 on the surfaces of the lands 21 and 22 increases the vibration transfer from the multi-layered ceramic capacitor 10 to the circuit board 20.

FIG. 5 is a plan view showing a circuit board in accordance with still another embodiment of the present invention.

Herein, the multi-layered ceramic capacitor 10 is mounted on the lands 21a, 21b, 22a and 22b of the circuit board 20 and the lands 21a, 21b, 22a and 22b can be formed in plural number by being separated to correspond to each edge portion of the external terminal electrodes 14a and 14b of the multi-layered ceramic capacitor 10 of FIG. 1 in order to reduce the soldering amount.

Although, in FIG. 5, the figure to form four lands in a shape of rectangle is represented as one embodiment, but there is no limitations for the shape thereof. However, since the height of the conductive material 15 on the surfaces of the lands 21a, 21b, 22a and 22b affects the vibration noise as described the above, there puts a certain limitation in the areas occupied by the lands 21a, 21b, 22a and 22b as shown in the following FIG. 6.

FIG. 6 is a simulation diagram for showing a relationship between the lands 21a, 21b, 22a and 22b and a width and a length of the multi-layered ceramic capacitor 10 in accordance with still another embodiment of the present invention. The width and the length of the multi-layered ceramic capacitor 10 are defied as W_{MLCC} and L_{MLCC}, respectively, as shown in FIG. 6. In case when the width occupied in the substrate with reference to the outer edges of one side land 21a (or 22a) and the other side land 21b (or 22b) is defined as W_{LAND(b)} and the length occupied in the substrate by the outer edges of one side land 21a (or 21b) and the other side land 22a (or 22b) is defined as L_{LAND(b)} as shown in FIG. 6, it is preferable that a relationship among the W_{MLCC}, the L_{MLCC}, the W_{LAND(b)} and the L_{LAND(b)} is as follows 0<L_{LAND(b)}/L_{MLCC}≦1.2, 0<W_{LAND(b)}/W_{MLCC}≦1.2. In the case of deviating from the range above, the large amount of the conductive material 15 on the surfaces of the lands 21a, 21b, 22a and 22b increases the vibration transfer from the multi-layered ceramic capacitor 10 to the circuit board 20.

On the other hands, in this case, it is preferable that a height T_{S} of the conductive material 15 to conductively connect the external terminal electrodes 14a and 14b to the lands 21 and 22 is less than ⅓ of a thickness T_{MLCC} of the multi-layered ceramic capacitor 10, and it is further preferable that the thickness T_{MLCC} of the multi-layered ceramic capacitor 10 is less than ¼. Herein, it can include a case that the height of the conductive material 15 is nearly 0 by forming the conductive material 15 only at a bottom portion of the external terminal electrodes 14a and 14b of the multi-layered ceramic capacitor 10.

On the other hands, in the present invention, the multi-layered ceramic capacitor 10 is taped in a horizontal direction and the width W_{MLCC} and the thickness T_{MLCC} can be equal or similar to each other. In case when the width is equal or similar to the thickness, although it is difficult to allow the multi-layered ceramic capacitor 10 to have the same directionality in general during the taping, the present invention can obtain the vibration reduction effect of circuit board by uniformly taping in the horizontal direction.

Packing Unit of the Multi-Layered Ceramic Capacitor

In order to supply a multi-layered ceramic capacitor 10 uniformly taped in the above-described horizontal direction, the present invention provides a packing unit of the multi-layered ceramic capacitor 10 uniformly aligned in the horizontal direction.

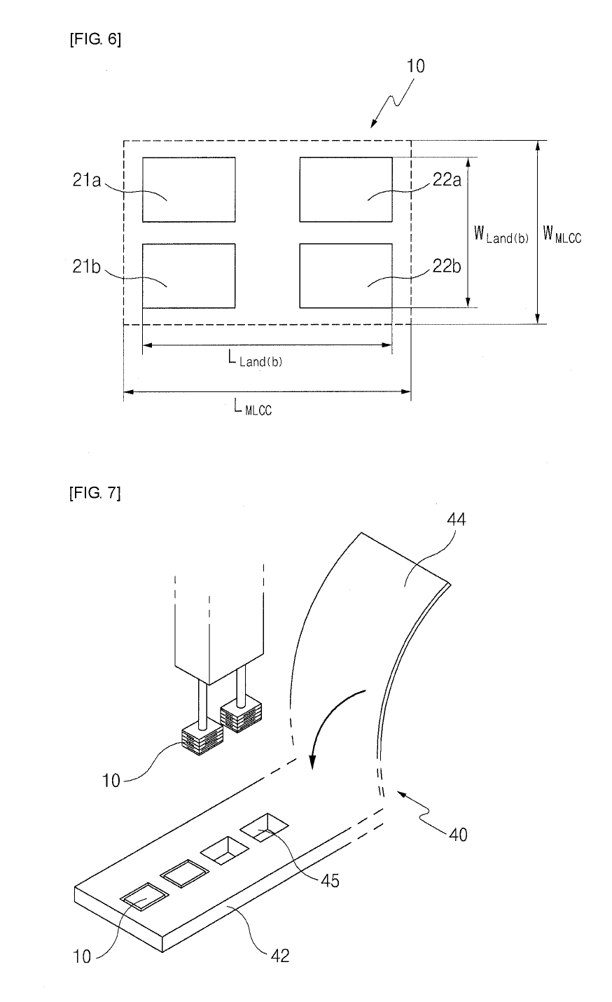

FIG. 7 is a diagram showing a packing unit for a multi-layered ceramic capacitor arranged horizontally in accordance with still another embodiment of the present invention, and

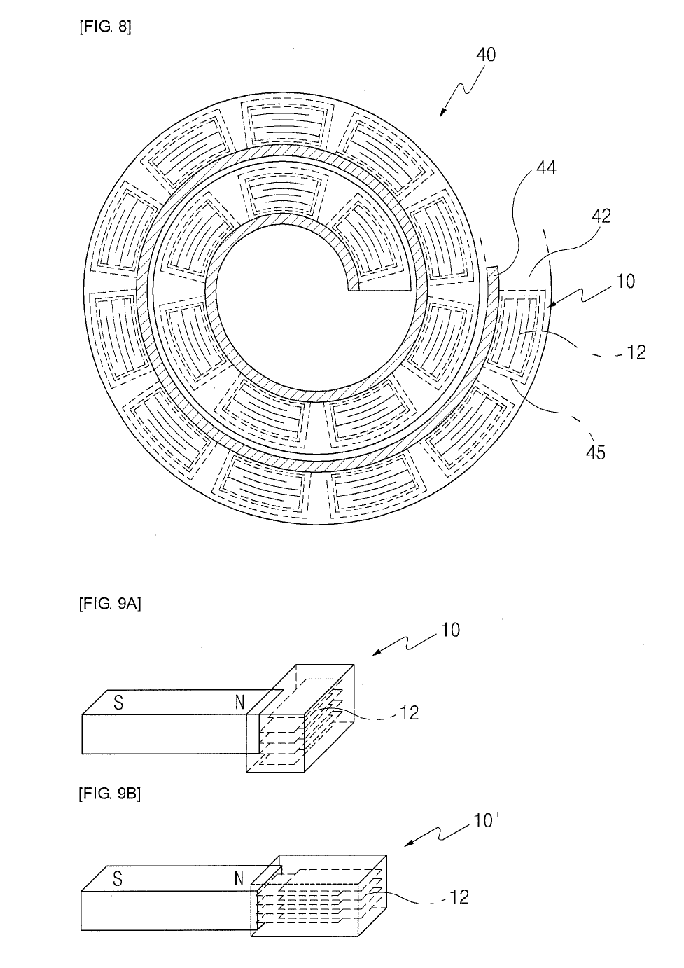

FIG. 8 is a diagram showing a packing unit for a multi-layered ceramic capacitor wound in a shape of reel in accordance with still another embodiment of the present invention.

Referring to FIG. 7, the multi-layered ceramic capacitor packing unit 40 of the embodiment of the present invention can include a packing sheet 42 having therein a storing space 45 to contain the multi-layered ceramic capacitor 10.

The storing space 45 of the packing sheet 42 has a shape corresponding to the multi-layered ceramic capacitor 10. The multi-layered ceramic capacitor 10 is moved from a transferring unit to the storing space 45 of packing unit 40 after the inner electrode 12 thereof is arranged horizontally with reference to a bottom surface of the storing space 45.

The multi-layered ceramic capacitor packing unit 40 can further include a packing layer 44 to cover the packing sheet 42 containing therein the multi-layered ceramic capacitor 10 of which the inner electrode 12 is horizontally arranged with reference to the bottom surface of the storing space 45.

FIG. 8 showing a packing unit for a multi-layered ceramic capacitor wound in a shape of reel can be formed by continuously winding the multi-layered ceramic capacitor packing unit 40 of the embodiment of FIG. 7 by a collecting roll (not shown).

Horizontal Direction Aligning Method of the Multi-Layered Ceramic Capacitor

In order to supply the multi-layered ceramic capacitor packing unit uniformly aligned in the horizontal direction of the above-described present invention, the present invention provides a horizontal direction alignment method of the multi-layered ceramic capacitor 10 having a width equal or similar to a thickness.

Herein, the equality and the similarity between the width and the thickness of the multi-layered ceramic capacitor 10 may be within a range of 0.75≦T_{MLCC}/W_{MLCC}≦1.25.

As described above, in order to drastically reduce the vibration noise due to the piezoelectric phenomenon of the multi-layered ceramic capacitor 10 having the width equal or similar to the thickness, it is required that the multi-layered ceramic capacitor 10 is aligned in the horizontal direction during the packing process so as to allow the inner electrode surface of the multi-layered ceramic capacitor 10 may to be in a horizontal direction on a circuit board surface.

For this, the present invention provides an alignment method using a magnetic field, in the present invention, as shown in FIG. 9. It utilizes such properties that, if a magnet comes close to a multi-layered ceramic capacitor, the multi-layered ceramic capacitor is attached to the magnet only in a shape of the multi-layered ceramic capacitor 10 and 10′ represented in FIGS. 9(a) and 9(b) so as to reduce a magnetic reluctance and it is not attached to the magnet in a shape of the multi-layered ceramic capacitor 10″ represented in FIG. 9(c).

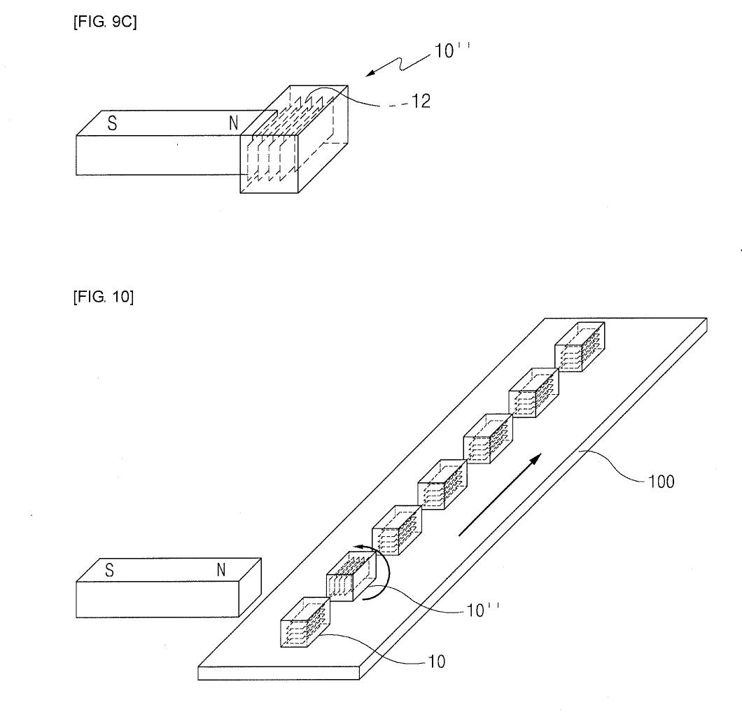

In order to put the multi-layered ceramic capacitor 10 having the width equal or similar to the thickness in the packing unit in the horizontal direction by using such properties, the magnet can be arranged around a side of transferring unit during a transferring process, as shown in FIG. 10.

In this case, the multi-layered ceramic capacitor 10″ shown in FIG. 9(c) is aligned by being rotated in the horizontal direction with reference to a transferring unit 100 by the magnetic force.

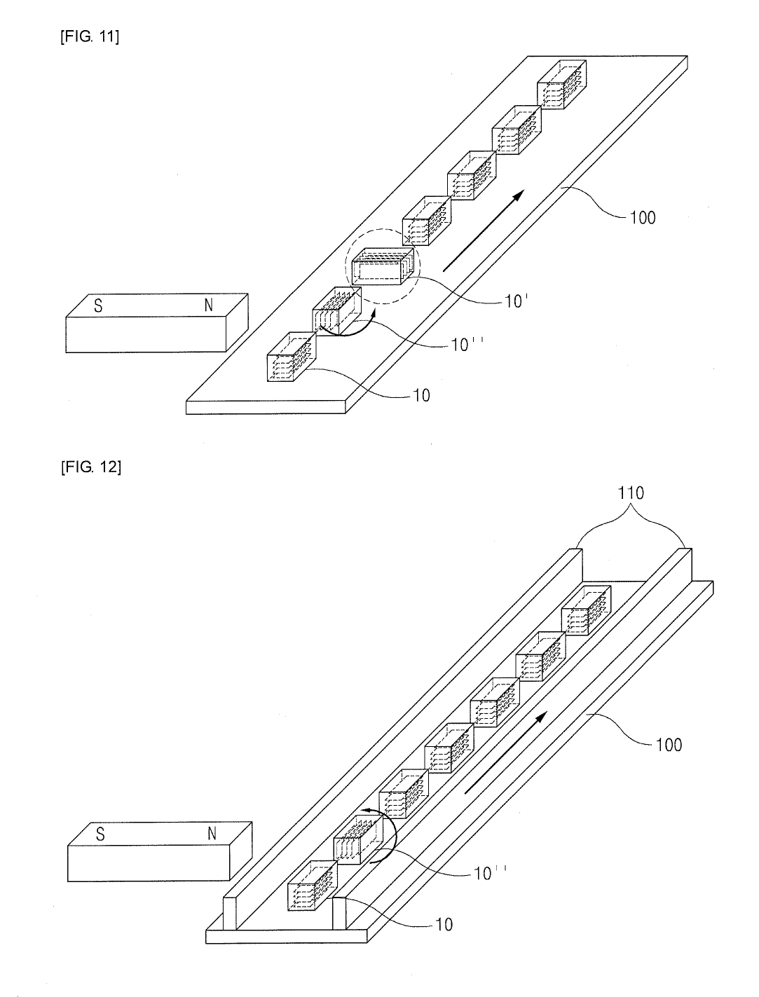

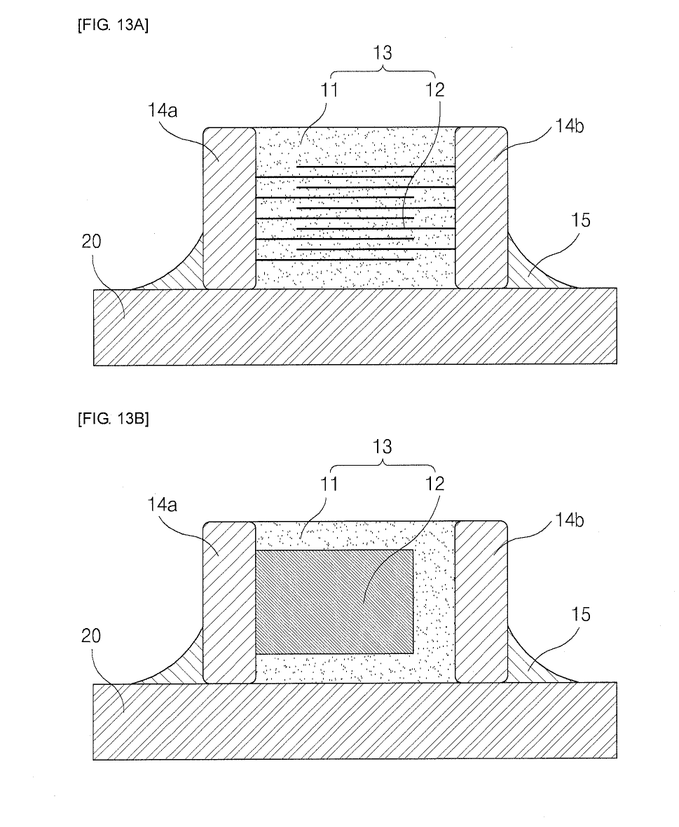

However, although there can be generated a case of being arranged in a shape equal to the multi-layered ceramic capacitor 10′ represented in FIG. 9(b) during the transferring process, as shown in FIG. 11, it can be solved by using a pair of guides 110 having a predetermined gap in the transferring unit 100 as shown in FIG. 12.

In this case, if a gap between the pair of guide units, a width, a thickness and a length of the multi-layered ceramic capacitor 10 are defined as g, W_{MLCC}, T_{MLCC} and L_{MLCC}, respectively, the following relationship can be satisfied:

\sqrt{(W²_{MLCC}+T²_{MLCC})}<g<min[\sqrt{(L²_{MLCC}+T²_{MLCC})},\sqrt{(L²_{MLCC}+W²_{MLCC})}]

Hereinafter, test examples will be explained in order to derive preferred embodiments of the present invention.

### Test Example 1

### Evaluation of the Effect of Height of the Conductive Material on the Vibration Noise in the Cases of Both Horizontally and Vertically Mounting the Multi-Layered Ceramic Capacitor on the Circuit Board

At first, in cases when the multi-layered ceramic capacitors are horizontally and vertically mounted on the circuit boards, in order to evaluate the effects of a height of solder on the vibration noise, the noise due to the vibration is measured as reducing the height of the solder by using a micro drill.

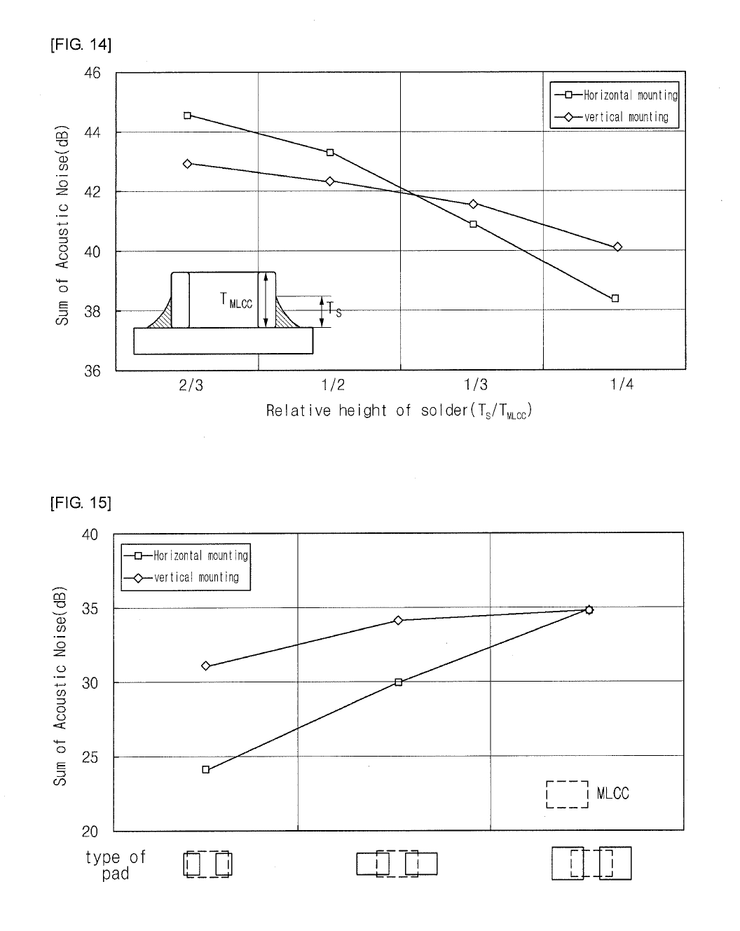

Simulation diagrams showing a case (a) when a multi-layered ceramic capacitor is horizontally mounted on a circuit board and a case (b) when a multi-layered ceramic capacitor is vertically mounted on a circuit board are shown in FIG. 13 and the measuring results are represented as a graph in FIG. 14.

As shown in FIG. 14, the vibration noise decreases in both cases of horizontal and vertical mounting as the height of the solder becomes lower. Particularly, the case of the horizontal mounting shows the greater decrease of the vibration noise than the case of the vertical mounting.

In view of such facts, the conductive material 15 such as the solder is estimated to play a role of vibration medium between the multi-layered ceramic capacitor 10 and the circuit board 20. Therefore, the vibration transfer from the multi-layered ceramic capacitor to the circuit board deteriorates as lowering the height of the conductive material 15. In the case of the horizontal mounting of the multi-layered ceramic capacitor on the circuit board, the main vibration surface of the multi-layered ceramic capacitor is estimated to be parallel to the surface of the circuit board. The vibration of the top surface of the multi-layered ceramic capacitor in the horizontal mounting is difficult to transfer to the circuit board in the case of low height of conductive material because there is no vibration medium around its top surface due to low height of conductive material. Therefore, as the height of conductive material becomes low, the vibration noise greatly decreases in the case of the horizontal mounting of the multi-layered ceramic capacitor on the circuit board. On the other hands, in the case of the vertical mounting of the multi-layered ceramic capacitor on the circuit board, the main vibration surface of the multi-layered ceramic capacitor is estimated to be perpendicular to the surface of the circuit board. The vibration of the side surface of the multi-layered ceramic capacitor in the vertical mounting can be transferred to the circuit board even in the case of low height of conductive material because there is a vibration medium around the bottom portion of its side surface in spite of low height of conductive material. Therefore, as the height of conductive material becomes low, the vibration noise decreases slowly in the case of the vertical mounting of the multi-layered ceramic capacitor on the circuit board but the decrease of vibration noise in the vertical mounting is much less than that in the horizontal mounting. From such results, it is preferable that the multi-layered ceramic capacitor 10 is mounted in the horizontal direction on the circuit board 20 and the soldering amount (height) is small in order to reduce the vibration noise.

### Test Example 2

### Evaluation of the Effect of the Sizes of the Lands on the Vibration Noise in the Cases of Both Horizontally and Vertically Mounting the Multi-Layered Ceramic Capacitor on the Circuit Board

Based on the change of the vibration noise according to the height of the solder in the test example 1, the vibration noise was additionally measured according to the sizes of the lands; these are represented as a graph in FIG. 15.

As shown in FIG. 15, the vibration noise decreases as the size of the land becomes smaller because the height of the solder is also reduced and therefore the vibration transfer efficiency from the multi-layered ceramic capacitor to the circuit board falls. It is confirmed that the vibration noise decreases drastically in the case of the horizontal mounting in comparison with the case of the vertical mounting as the size of the land becomes smaller.

On the other hands, the sizes of the multi-layered ceramic capacitor 10 may be 0603(L×W=0.6 mm×0.3 mm), 1005, 1608, 2012, 3216 and 3225 or the like according to the width W and the length L of the multi-layered ceramic capacitor 10 of FIG. 2. In case when the size of the multi-layered ceramic capacitor 10 is equal to or larger than 3216, the effects of drastically reducing the vibration noise are confirmed from the cases that the multi-layered ceramic capacitors of all sizes mentioned above are horizontally mounted and the sizes of the lands are small. However, since the absolute amount of the conductive material 15 is large even though the relative height of the conductive material 15 is low in comparison with the thickness of the multi-layered ceramic capacitor 10 in case when the size of the multi-layered ceramic capacitor 10 is equal to or larger than 3216, it can be identified that the relative height of the conductive material 15 should be further lowered in order to increase the reduction effect of the vibration noise.

In accordance with the method of mounting the circuit board of the multi-layered ceramic capacitor of the present invention and the land pattern of the circuit board for the same, they have effects to drastically reduce the generation of noise by prohibiting the vibration generated in the multi-layered ceramic capacitor from transferring to the substrate with a simple method.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. A mounting structure of a circuit board having thereon a multi-layered ceramic capacitor on which a plurality of dielectric sheet having internal electrodes formed thereon are stacked and external terminal electrodes connected to the internal electrodes in parallel are formed on both ends thereof comprising:
lands of a circuit board which are conductively connected to the external terminal electrodes in such a way that internal electrode layers of the multi-layered ceramic capacitor and the circuit board are arranged in a horizontal direction,
wherein a height T_{S} of conductive material to conductively connect the external terminal electrodes to the lands is less than ⅓ of a thickness T_{MLCC} of the multi-layered ceramic capacitor.

2. The mounting structure of the circuit board having thereon the multi-layered ceramic capacitor according to claim 1, wherein the multi-layered ceramic capacitor is taped to be mounted in a horizontal direction and has the thickness T_{MLCC} equal or similar to a width W_{MLCC}.

3. The mounting structure of the circuit board having thereon the multi-layered ceramic capacitor according to claim 1, wherein the number of dielectric layers of the multi-layered ceramic capacitor is more than 200 layers.

4. The mounting structure of the circuit board having thereon the multi-layered ceramic capacitor according to claim 1, wherein a dielectric layer thickness of the multi-layered ceramic capacitor is less than 3 μm.

5. The mounting structure of the circuit board having thereon the multi-layered ceramic capacitor according to claim 1, wherein the number of dielectric layers of the multi-layered ceramic capacitor is more than 200 layers and a dielectric layer thickness of the multi-layered ceramic capacitor is less than 3 μm.

6. A method of mounting a circuit board having thereon a multi-layered ceramic capacitor on which a plurality of dielectric sheet having internal electrodes formed thereon are stacked and external terminal electrodes connected to the internal electrodes in parallel are formed on both ends thereof comprising:
conductively connecting lands of a circuit board to the external terminal electrodes in such a way that internal electrode layers of the multi-layered ceramic capacitor and the circuit board are arranged in a horizontal direction,
wherein a height T_{S} of conductive material to conductively connect the external terminal electrodes to the lands is less than ⅓ of a thickness T_{MLCC} of the multi-layered ceramic capacitor.

7. The method of mounting the circuit board having thereon the multi-layered ceramic capacitor according to claim 6, wherein the multi-layered ceramic capacitor is taped to be mounted in a horizontal direction and has the thickness T_{MLCC} equal or similar to a width W_{MLCC}.

8. The method of mounting the circuit board having thereon the multi-layered ceramic capacitor according to claim 6, wherein the number of dielectric layers of the multi-layered ceramic capacitor is more than 200 layers.

9. The method of mounting the circuit board having thereon the multi-layered ceramic capacitor according to claim 6, wherein the a dielectric layer thickness of the multi-layered ceramic capacitor is less than 3 μm.

10. The method of mounting the circuit board having thereon the multi-layered ceramic capacitor according to claim 6, wherein the number of dielectric layers of the multi-layered ceramic capacitor is more than 200 layers and a dielectric layer thickness of the multi-layered ceramic capacitor is less than 3 μm.

11. A method of mounting a circuit board having thereon a multi-layered ceramic capacitor on which a plurality of dielectric sheet having internal electrodes formed thereon are stacked and external terminal electrodes connected to the internal electrodes in parallel are formed on both ends thereof comprising:
forming lands to mount the multi-layered ceramic capacitor on a surface of the circuit board,
wherein the lands of the circuit board are conductively connected to the external terminal electrodes in such a way that internal electrode layers of the multi-layered ceramic capacitor and the circuit board are arranged in a horizontal direction;
the lands are formed in a plural number on a surface of the circuit board by being separated so as to correspond to portions on which the external terminal electrodes of the multi-layered ceramic capacitor are formed; and
if a width and a length of the multi-layered ceramic capacitor are defined as W_{MLCC} and L_{MLCC}, respectively, and a W_{LAND(a)} and a L_{LAND(a)} are defined as a width and a length occupied at the circuit board from an outside edge of any one land among separated lands to an outside edge of another land,
a relationship among the W_{MLCC}, the L_{MLCC}, the W_{LAND(a)} and the L_{LAND(a)} is as follows:
0<L_{LAND(a)}/L_{MLCC},≦1.2,0<W_{LAND(a)}/W_{MLCC}≦1.2

12. A method of mounting a circuit board having thereon a multi-layered ceramic capacitor on which a plurality of dielectric sheet having internal electrodes formed thereon are stacked and external terminal electrodes connected to the internal electrodes in parallel are formed on both ends thereof comprising:
forming lands to mount the multi-layered ceramic capacitor on a surface of the circuit board,
wherein the lands of the circuit board are conductively connected to the external terminal electrodes in such a way that internal electrode layers of the multi-layered ceramic capacitor and the circuit board are arranged in a horizontal direction; and
the lands are formed in a plural number on a surface of the circuit board by being separated so as to correspond to edge portions of the external terminal electrodes of the multi-layered ceramic capacitor to reduce an amount of soldering.

13. The method of mounting the circuit board having thereon the multi-layered ceramic capacitor according to claim 12, wherein if a width and a length of the multi-layered ceramic capacitor are defined as W_{MLCC} and L_{MLCC}, respectively, and a W_{LAND(b)} and a L_{LAND(b)} are defined as a width and a length occupied at the circuit board from an outside edge of any one land among separated lands to an outside edge of another land,
a relationship among the W_{MLCC}, the L_{MLCC}, the W_{LAND(b)} and the L_{LAND(b)} is as follows:
0<L_{LAND(b)}/L_{MLCC},≦1.2,0<W_{LAND(b)}/W_{MLCC}≦1.2.

14. The method of mounting the circuit board having thereon the multi-layered ceramic capacitor according to claim 11, wherein a height T_{S} of conductive material to conductively connect the external terminal electrodes to the lands is less than ⅓ of a thickness T_{MLCC} of the multi-layered ceramic capacitor.

15. The method of mounting the circuit board having thereon the multi-layered ceramic capacitor according to claim 11, wherein the multi-layered ceramic capacitor is taped to be mounted in a horizontal direction and has the thickness T_{MLCC} equal or similar to a width W_{MLCC}.

16. The method of mounting the circuit board having thereon the multi-layered ceramic capacitor according to claim 14, wherein the multi-layered ceramic capacitor is taped to be mounted in a horizontal direction and has the thickness T_{MLCC} equal or similar to a width W_{MLCC}.

17. A land pattern on a circuit board having thereon a multi-layered ceramic capacitor on which a plurality of dielectric sheet having internal electrodes formed thereon are stacked and external terminal electrodes connected to the internal electrodes in parallel are formed on both ends thereof,
wherein the land pattern is formed in a plural number on a surface of the circuit board by being separated so as to correspond to portions of the external terminal electrodes of the multi-layered ceramic capacitor,
wherein if a width and a length of the multi-layered ceramic capacitor are defined as W_{MLCC} and L_{MLCC}, respectively, and a W_{LAND(a)} and a L_{LAND(a)} are defined as a width and a length occupied at the circuit board from an outside edge of any one land among separated lands to an outside edge of another land,
a relationship among the W_{MLCC}, the L_{MLCC}, the W_{LAND(a)} and the L_{LAND(a)} is as follows:
0<L_{LAND(a)}/L_{MLCC},≦1.2,0<W_{LAND(a)}/W_{MLCC}≦1.2

18. A land pattern on a circuit board having thereon a multi-layered ceramic capacitor on which a plurality of dielectric sheet having internal electrodes formed thereon are stacked and external terminal electrodes connected to the internal electrodes in parallel are formed on both ends thereof,
wherein the land pattern is formed in a plural number on a surface of the circuit board by being separated so as to correspond to edge portions of the external terminal electrodes of the multi-layered ceramic capacitor to reduce an amount of soldering,
wherein if a width and a length of the multi-layered ceramic capacitor are defined as W_{MLCC} and L_{MLCC}, respectively, and a W_{LAND(b)} and a L_{LAND(b)} are defined as a width and a length occupied at the circuit board from an outside edge of any one land among separated lands to an outside edge of another land,
a relationship among the W_{MLCC}, the L_{MLCC}, the W_{LAND(b)} and the L_{LAND(b)} is as follows:
0<L_{LAND(b)}/L_{MLCC},≦1.2,0<W_{LAND(b)}/W_{MLCC}≦1.2.

19. A packing unit for a multi-layered ceramic capacitor comprising:
the multi-layered ceramic capacitor on which a plurality of dielectric sheet having internal electrodes formed thereon are stacked and external terminal electrodes connected to the internal electrodes in parallel are formed on both ends thereof; and
a packing sheet including a storing space to contain the multi-layered ceramic capacitor,
wherein internal electrodes thereof are aligned to be horizontally arranged with reference to a bottom surface of the storing space.

20. The packing unit for the multi-layered ceramic capacitor according to claim 19, further comprising:
a packing layer coupled to the packing sheet and to cover the multi-layered ceramic capacitor.

21. The packing unit for the multi-layered ceramic capacitor according to claim 19, wherein the packing unit for the multi-layered ceramic capacitor is wound in a shape of reel.

22. The packing unit for the multi-layered ceramic capacitor according to claim 19, wherein the multi-layered ceramic capacitor is taped to be mounted in a horizontal direction and has the thickness T_{MLCC} equal or similar to a width W_{MLCC}.

23. The packing unit for the multi-layered ceramic capacitor according to claim 21, wherein the multi-layered ceramic capacitor is taped to be mounted in a horizontal direction and has the thickness T_{MLCC} equal or similar to a width W_{MLCC}.

24. A method of aligning a multi-layered ceramic capacitor having a thickness T_{MLCC} equal or similar to a width W_{MLCC} in a horizontal direction comprising:
mounting the multi-layered ceramic capacitor on a transferring unit to transfer continuously; and
supplying magnetic field to the multi-layered ceramic capacitor transferred in the transferring unit in order to align the inner electrode layers thereof in the same direction.

25. The method of aligning a multi-layered ceramic capacitor horizontally in the packing unit for the multi-layered ceramic capacitor according to claim 24, wherein the inner electrode layer of the multi-layered ceramic capacitor is arranged horizontally with reference to a bottom plane of the transferring unit by supplying magnetic field.

26. The method of aligning a multi-layered ceramic capacitor horizontally in the packing unit for the multi-layered ceramic capacitor according to claim 24, wherein the transferring unit further comprises:
a pair of guide units to align the inner electrode layer of the multi-layered ceramic capacitor.

27. The method of aligning a multi-layered ceramic capacitor horizontally in the packing unit for the multi-layered ceramic capacitor according to claim 26, wherein if a gap between the pair of guide units and a width, a thickness and a length of the multi-layered ceramic capacitor are defined as g, W_{MLCC}, T_{MLCC} and L_{MLCC}, respectively, the following relationship is satisfied:
\sqrt{(W²_{MLCC}+T²_{MLCC})}<g<min[\sqrt{(L²_{MLCC}+T²_{MLCC})},\sqrt{(L²_{MLCC}+W²_{MLCC})}].
